(19) United States
(12) Patent Application Publication
(10) Pub. No.: US 2011/0186847 A1
(43) Pub. Date: Aug. 4, 2011

(54) ORGANIC LIGHT EMITTING DIODE DISPLAY AND FABRICATING METHOD OF THE SAME

(75) Inventors: Jong-Yun Kim, Yongin-city (KR); Il-Jeong Lee, Yongin-city (KR); Do-Hyun Kwon, Yongin-city (KR); Jong-Mo Yeo, Yongin-city (KR)

(73) Assignee: Samsung Mobile Display Co., Ltd., Yongin-city (KR)

(21) Appl. No.: 13/020,687

(22) Filed: Feb. 3, 2011

(30) Foreign Application Priority Data
Feb. 3, 2010 (JP) 10-2010-0010012

(51) Int. Cl. H01L 51/52; H01L 51/56

(52) U.S. Cl. 257/59; 438/34; 257/E51.018; 257/E27.119

(57) ABSTRACT

An organic light emitting diode display and a fabricating method of the same are disclosed. In one embodiment, the display includes i) a substrate having a thin film transistor region and a pixel region, ii) a semiconductor layer formed in the thin film transistor region, iii) a gate insulating layer formed on the substrate and the semiconductor layer and vi) a lower electrode formed on the gate insulating layer, wherein the lower electrode is formed in the pixel region. The display further includes i) a gate electrode formed on the gate insulating layer, wherein the gate electrode is formed substantially directly above the semiconductor layer, ii) an interlayer insulating layer formed on the gate insulating layer, the lower electrode and the gate electrode and iii) source and drain electrodes formed on the interlayer insulating layer and electrically connected with the semiconductor layer. Each of the lower electrode and the gate electrode is formed of a first conductive layer and a second conductive layer formed on the first conductive layer. The second conductive layer and the source/drain electrodes are formed of the same material.

### RELATED APPLICATIONS

This application claims priority to and the benefit of Korean Patent Application No. 10-2010-0010012 filed in the Korean Intellectual Property Office on Feb. 3, 2010, the entire contents of which are incorporated herein by reference.

### BACKGROUND

1. Field

The described technology generally relates to an organic light emitting diode display and a fabricating method of the same.

2. Description of the Related Technology

An organic light emitting diode (OLED) display is a type of self-emissive flat panel display. OLED displays emit light when electrons and holes are injected into an organic light emitting layer from an electron injection electrode (cathode) and a hole injection electrode (anode), respectively and excitons formed by combining the injected electrons and holes with each other fall from an excited state to a ground state.

In general, OLED displays include i) substrates facing each other and ii) an organic light emitting diode including a first electrode, a second electrode, and an organic light emitting layer positioned between the first electrode and the second electrode.

Organic light emitting diode (OLED) displays may be formed as an active type which includes a thin film transistor for controlling light emission of the OLED. In this design, a plurality of electrodes are used to form the thin film transistor and the electrodes are generally formed through deposition, photolithography process and etching processes.

Several additional processes are generally needed in order to form the patterned electrodes. Such added processes delay product manufacturing time and increase the risk of manufacturing defects, and a reduction of yield.

### SUMMARY

One inventive aspect is an organic light emitting diode display having advantages of simplifying a manufacturing process, ensuring reliability, and easily performing an etching process.

Another aspect is a fabricating method of the organic light emitting diode display.

Another aspect is a method capable of etching both the gate electrode and the source/drain electrode while ensuring the reliability.

Another aspect is an organic light emitting diode display that includes: a substrate; a semiconductor layer formed in a thin film transistor region on the substrate; a gate insulating layer formed throughout the entire surface of the substrate including the semiconductor layer; a lower electrode formed in a pixel region of the substrate on the gate insulating layer; a gate electrode formed corresponding to the semiconductor layer on the gate insulating layer; an interlayer insulating layer formed on the entire surface of the gate insulating layer including the lower electrode and the gate electrode and exposing a part of the lower electrode; and source and drain electrodes formed on the interlayer insulating layer and connected with the semiconductor layer. In addition, the lower electrode and the gate electrode are formed by a first conductive layer and a second conductive layer, respectively and the second conductive layer and the source/drain electrodes are a single layer made of the same material.

Another aspect is a fabricating method of an organic light emitting diode display that includes: forming a semiconductor layer in a thin film transistor region on a substrate; forming a gate insulating layer throughout the entire surface of the substrate including the semiconductor layer; forming a lower electrode in a pixel region of the substrate on the gate insulating layer and forming a gate electrode in the thin film transistor region of the substrate; forming an interlayer insulating layer on the entire surface of the gate insulating layer including the lower electrode and the gate electrode and forming first and second contact holes for exposing a part of the lower electrode and third and fourth contact holes for exposing source and drain domains of the semiconductor layer; and forming a source/drain electrode layer on the interlayer insulating layer and forming source and drain electrodes through a mask process. In addition, the lower electrode and the gate electrode are formed by a first conductive layer and a second conductive layer, respectively and the second conductive layer and the source/drain electrodes are a single layer made of the same material.

The second conductive layer and the source and drain electrodes may be made of an Al alloy acquired by adding Co, Ge, and La.

Co may be added at 0.2 to 1.0 atom %, Ge may be added at 0.5 to 1.0 atom %, and La may be added at 0.1 to 0.5 atom %. Another aspect is an organic light emitting diode display, comprising: a substrate having a thin film transistor region and a pixel region; a semiconductor layer formed in the thin film transistor region; a gate insulating layer formed on the substrate and the semiconductor layer; a lower electrode formed on the gate insulating layer, wherein the lower electrode is formed in the pixel region; a gate electrode formed on the gate insulating layer, wherein the gate electrode is formed substantially directly above the semiconductor layer; an interlayer insulating layer formed on the gate insulating layer, the lower electrode and the gate electrode; and source and drain electrodes formed on the interlayer insulating layer and electrically connected with the semiconductor layer, wherein each of the lower electrode and the gate electrode is formed of a first conductive layer and a second conductive layer formed on the first conductive layer, and wherein the second conductive layer and the source/drain electrodes are formed of the same material.

In the above display, the first conductive layer is formed of at least one of the following: ITO, IZO, In203, and Sn203. In the above display, the second conductive layer and the source and drain electrodes is formed of an Al alloy containing i) one of Co and Ni, ii) one of Ge and Si, and iii) La. In the above display, the Al alloy contains Co or Ni of about 0.2 atom % to about 1.0 atom % of the Al alloy. In the above display, the Al alloy contains Ge of about 0.5 atom % to about 1.0 atom % of the Al alloy. In the above display, the Al alloy contains Si of about 0.3 atom % to about 1.0 atom % of the Al alloy. In the above display, the Al alloy contains La of about 0.1 atom % to about 0.5 atom % of the Al alloy.

In the above display, an opening is defined in the second conductive layer of the lower electrode. The above display further comprises: a pixel defining layer is formed on the entire surface of the interlayer insulating layer and the source and drain electrodes, the pixel defining layer has an opining exposing a part of the first conductive layer; an organic layer formed on the opening of the pixel defining layer; and an upper electrode formed on the interlayer insulating layer and the organic layer. In the above display, the gate electrode has a thickness of about 2000 Å to about 5000 Å.

Another aspect is a method of manufacturing an organic light emitting diode display, comprising: providing a substrate having a thin film transistor region and a pixel region; forming a semiconductor layer in the thin film transistor region, wherein the semiconductor layer has a source domain, a drain domain and a channel domain interposed between the source and drain domains; forming a gate insulating layer on the substrate and the semiconductor layer; forming a lower electrode on the gate insulating layer, wherein the lower electrode is formed in the pixel region; forming a gate electrode on the gate insulating layer, wherein the gate electrode is formed substantially directly above the channel domain of the semiconductor layer; forming an interlayer insulating layer on i) the gate insulating layer, ii) the lower electrode and iii) the gate electrode; forming first and second contact holes so as to expose part of the lower electrode; forming third and fourth contact holes so as to expose the source and drain domains of the semiconductor layer; and forming a source/drain electrode layer on the interlayer insulating layer; and performing a mask process on the source/drain electrode layer so as to form source and drain electrodes, wherein each of the lower electrode and the gate electrode is formed of a first conductive layer and a second conductive layer formed on the first conductive layer, and wherein the second conductive layer and the source and drain electrodes are formed of the same material.

The above method further comprises: etching the second conductive layer of the lower electrode so as to expose part of the first conductive layer of the lower electrode, wherein the etching is performed via the same mask process used to form the source and drain electrodes. In the above method, the first conductive layer is formed from one of: ITO, IZO, In203, and Sn203.

In the above method, each of the second conductive layer and the source and drain electrodes is formed of an Al alloy containing i) one of Co and Ni, ii) one of Ge and Si, and iii) La. The above method further comprises: electrically connecting a portion of the lower electrode exposed through the second contact hole and portions of the source and drain domains exposed through the third contact hole by one of the source and drain electrodes. In the above method, the lower electrode and the gate electrode are formed through the same mask process.

Another aspect is a method of manufacturing an organic light emitting diode display, comprising: providing a substrate having a thin film transistor region and a pixel region; forming a semiconductor layer in the thin film transistor region, wherein the semiconductor layer has a source domain, a drain domain and a channel domain interposed between the source and drain domains; forming a gate insulating layer on the substrate and the semiconductor layer; forming a lower electrode on the gate insulating layer, wherein the lower electrode is formed in the pixel region; forming a gate electrode on the gate insulating layer, wherein the gate electrode is formed substantially directly above the channel domain of the semiconductor layer, and wherein each of the lower electrode and the gate electrode is formed of a first conductive layer and a second conductive layer formed on the first conductive layer; forming an interlayer insulating layer on i) the gate insulating layer, ii) the lower electrode and iii) the gate electrode; performing a mask process on i) the source/drain electrode layer so as to form source and drain electrodes; and etching the second conductive layer of the lower electrode so as to expose part of the first conductive layer of the lower electrode, wherein the etching is performed via the same mask process used to form the source and drain electrodes.

In the above method, each of the second conductive layer and the source and drain electrodes is formed of an Al alloy containing i) one of Co and Ni, ii) one of Ge and Si, and iii) La. In the above method, the second conductive layer and the source and drain electrodes are formed of the same material.

### BRIEF DESCRIPTION OF THE DRAWINGS

FIGS. 1A to 1H are cross-sectional views for describing a fabricating process of an organic light emitting diode display according to an embodiment.

FIG. 2 is a picture of a cross section after forming a source/drain electrode and a pixel defined layer photographed by using a scanning electron microscope (SEM).

FIG. 3 is a picture of a plane after performing a sour/drain film-forming process and a pixel defined layer forming process photographed by using a microscope.

FIG. 4 is a picture of a cathode contact portion photographed by using a microscope in order to verify whether or not hillock is generated.

FIG. 5 is a picture of a cross section after BOE-washing a contact hole of a pixel region photographed by using an SEM.

### DETAILED DESCRIPTION

In view of this inefficiency, a method for decreasing the number of times that a mask is used and various methods for etching both a gate electrode and a source/drain electrode has been studied.

In general, when the gate electrode and the source/drain electrode are made of a single material, each of the gate electrode and the source/drain electrode has a chemical formation of Mo/Al/Mo. However, in such a structure, the molybdenum material of a pad part corrodes, and as a result, reliability is reduced.

However, when the gate electrode has the chemical formation of Mo/Al/Mo and the source/drain electrode has a structure of Ti/Al/Ti, reliability may be enhanced. But, since the electrodes are made of different materials, it is difficult to develop an etching solution that is satisfactory for both. Furthermore, when the gate electrode and the source/drain electrode are separately etched, the aluminum of the source/drain electrode may be etched by an etching solution used for the gate electrode.

Further, when both the gate electrode and the source/drain electrode have the same structure of Ti/Al/Ti, the reliability in the pad part may be enhanced and batch-type etching is possible. But Ti, which is the top of the gate electrode, adversely affected by HF or Hydrofluoric acid at the time of washing a contact hole and before forming a film of the source/drain electrode.

Herein, an organic light emitting diode (OLED) display and a fabricating method of the same according to embodiments will be described with reference to the accompanying drawings showing certain embodiments.

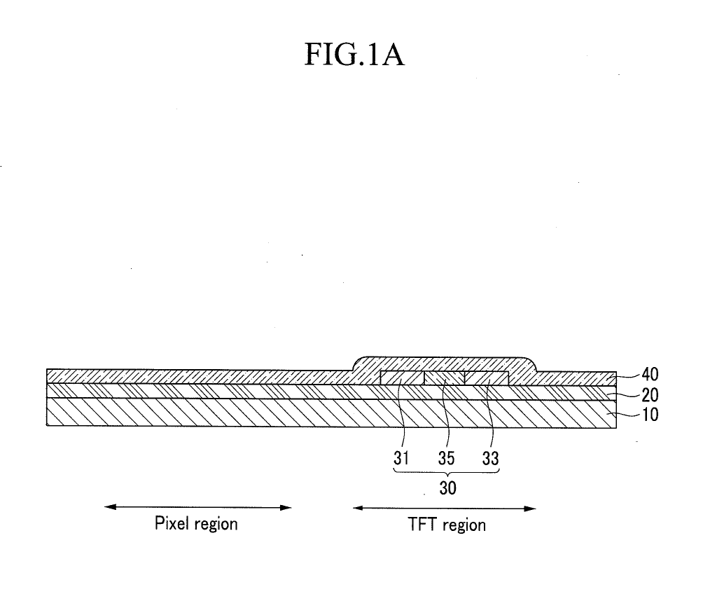

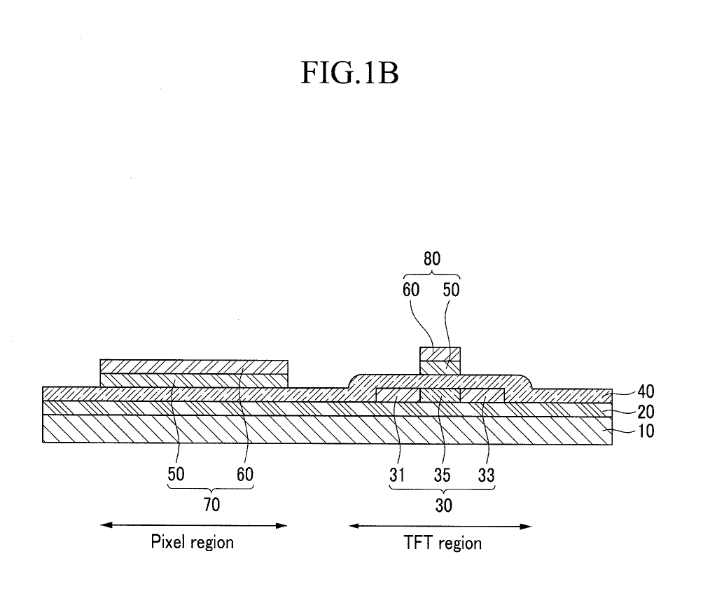

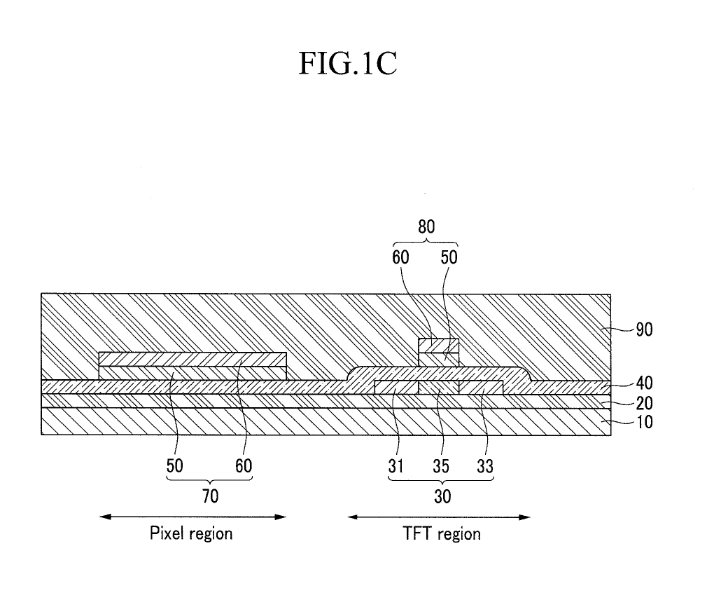

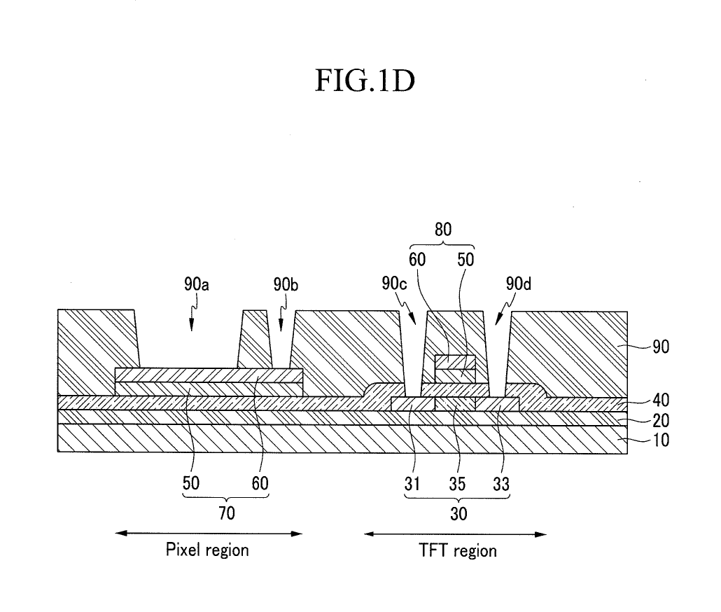

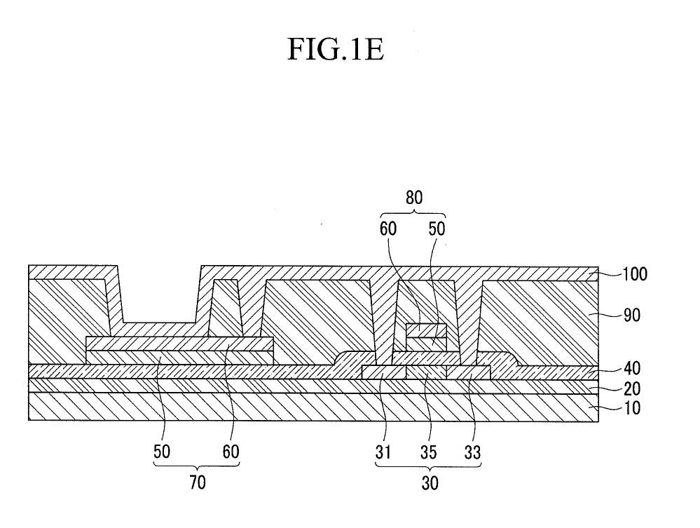

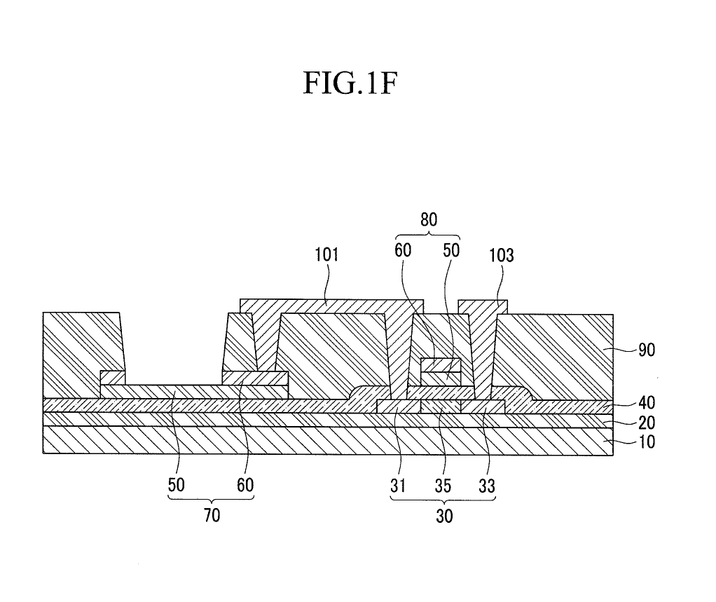

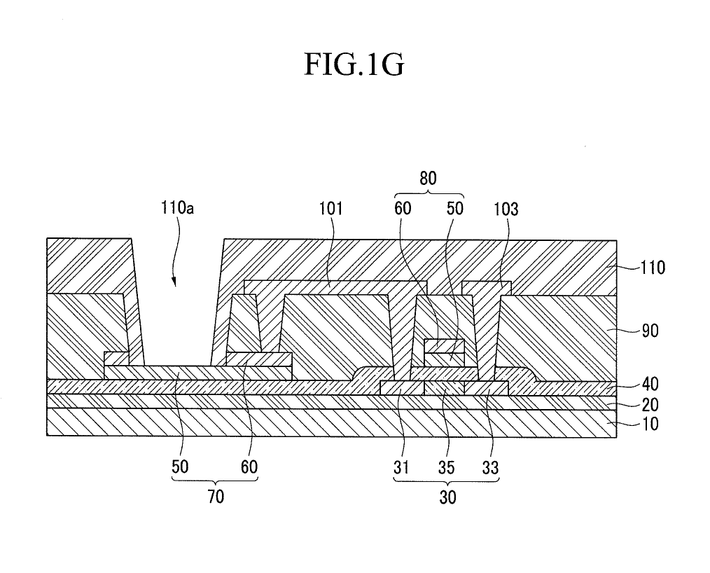

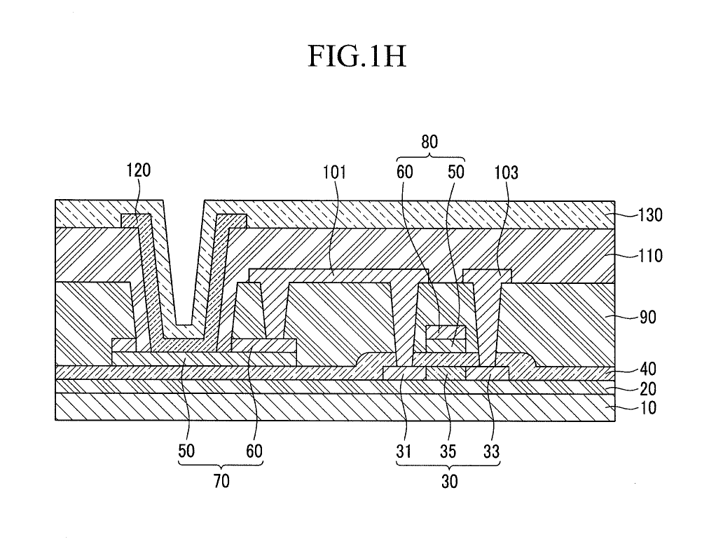

FIGS. 1A to 1H are cross-sectional views for describing a fabricating process of an OLED display according to an embodiment.

As shown in FIG. 1A, a buffer layer 20 is formed on substantially the entire surface of a substrate 10 and a patterned semiconductor layer 30 is formed on the buffer layer 20 through a first mask process. Various plastic substrates such as acryl as well as a glass substrate or a metallic substrate may be used as the substrate 10.

The buffer layer 20 prevents the semiconductor layer 30 from being contaminated by the substrate 10. The buffer layer 20 may not be formed depending on a process environment or selection of those skilled in the art.

An amorphous silicon layer is formed on the buffer layer 210 through deposition methods such as PECVD, LPCVD, etc., and the amorphous silicon layer is crystallized by using, for example, excimer laser annealing (ELA), a sequential lateral solidification (SLS), metal induced crystallization (MIC), or metal induced lateral crystallization (MILC) and patterned by using an etching process so as to form the semiconductor layer 30 in a thin-film transistor region (TFT region) within a unit pixel.

The semiconductor layer 30 includes source and drain domains 31 and 33 and a channel domain 35 positioned between the source and drain domains 31 and 33. The source and drain domains 31 and 33 are formed by ion-injecting an impurity having predetermined conductivity, i.e., an n-type impurity or a p-type impurity. In the channel domain 35, a channel is formed by driving a thin film transistor.

Thereafter, a gate insulating layer 40 is formed on substantially the entire surface of the substrate 10 and the semiconductor layer 30. The gate insulating layer 40 may be formed at least partially of a silicon oxide or a silicon nitride, or formed in a lamination structure thereof.

Thereafter, as shown in FIG. 1B, a first conductive layer 50 and a second conductive layer 60 formed on the first conductive layer 50 are formed in a pixel region and the TFT region.

In one embodiment, the first conductive layer 50 and the second conductive layer 60 are formed by depositing a material of the first conductive layer 50 on the gate insulating layer 40 and depositing a material of the second conductive layer 60 on the first conductive layer 50 and patterning the materials through a second mask process.

In this embodiment, a laminated film of the first and second conductive layers 50 and 60, which is formed in the pixel region serves as a lower electrode 70 of an OLED. Further, a laminated film of the first conductive layer 50 and the second conductive layer 60, which is formed in the TFT region serves as a gate electrode 80 of the thin film transistor. Lamination thicknesses of the first and second conducive layers 50 and 60 may have about 2000 Å to about 5000 Å.

All materials used as the material of the lower electrode 70 in the field of the OLED may be used as the material of the first conductive layer 50 and, for example, a transparent metallic material such as indium tin oxide (ITO), IZO, In203, or Sn203 may be used.

In one embodiment, an aluminum alloy acquired by adding Co, Ge, and La to aluminum (Al) is used as the material of the second conductive layer 60 and will be described below.

Thereafter, as shown in FIGS. 1C and 1D, an interlayer insulating layer 90 is formed on substantially the entire surface of the gate insulating layer 40, and the lower electrode 70 and the gate electrode 80. Then, first and second contact holes 90a and 90b for exposing the second conductive layer 60 of the lower electrode 70 and third and fourth contact holes 90c and 90d for exposing the source and drain domains 31 and 33 of the semiconductor layer 30, respectively are formed through a third mask process.

Thereafter, as shown in FIGS. 1E and 1F, a source/drain electrode layer 100 is formed by depositing a source/drain electrode material on substantially the entire surface and source and drain electrodes 101 and 103 are formed through a fourth mask process. The aluminum alloy acquired by adding Co, Ge, and La to aluminum (Al) is used as a material of the source/drain electrode layer 100. In one embodiment, the source and drain electrodes 101 and 103 and the second conductive layer 60 are formed of the same material. At this time, the source and drain electrodes 101 and 103 may have a thickness of about 3000 Å to about 6000 Å.

As such, since the source and drain electrodes 101 and 103 and the second conductive layer 60 are formed of the same material, the second conductive layer 60 exposed by the first contact hole 90a of the pixel region may be etched together while the source and drain electrodes 101 and 103 are formed.

At this time, the second conductive layer 60 is etched, as a result, the first conductive layer 50 positioned below the second conductive layer 60 is exposed through the first contact hole 90a.

Thereafter, as shown in FIG. 1G, a pixel defined layer 110 for defining a pixel on substantially the entire surface is laminated and an opening 110a for exposing the first conductive layer 50 of the lower electrode 70 is formed through a fifth mask process.

Thereafter, as shown in FIG. 1H, an organic layer 120 including a light emitting layer is formed on the opening 110a and an upper electrode 130 is formed on substantially the entire surface of the pixel defined layer 110 and the organic layer 120 so as to fabricate an active drive type OLED display having an OLED of which light emission is controlled by the thin film transistor in the pixel.

In at least one of the disclosed embodiments, when the single layer formed by the aluminum alloy acquired by adding Co, Ge, and La to aluminum (Al) is used as the material of the second conductive layer 60 and the source and drain electrodes 101 and 103, the following effects can be obtained.

First, in the case in which the OLED display is fabricated through the above-mentioned processes, the first conductive layer 50 of the lower electrode 70 of the OLED can be exposed by etching both the second conductive layer 60 and the source/drain electrode layer 100 in the pixel region through one mask process, thereby decreasing the number of mask processes.

Further, in the case of a bi-layer or a triple-layer, since etching speeds and time of layers are different from each other, it is difficult to develop a common etching solution, but in the case of the single aluminum alloy layer, since the single aluminum alloy layer is easily etched by a phosphoric/nitric/acetic acid-based etching solution, it is easy to develop the common etching solution.

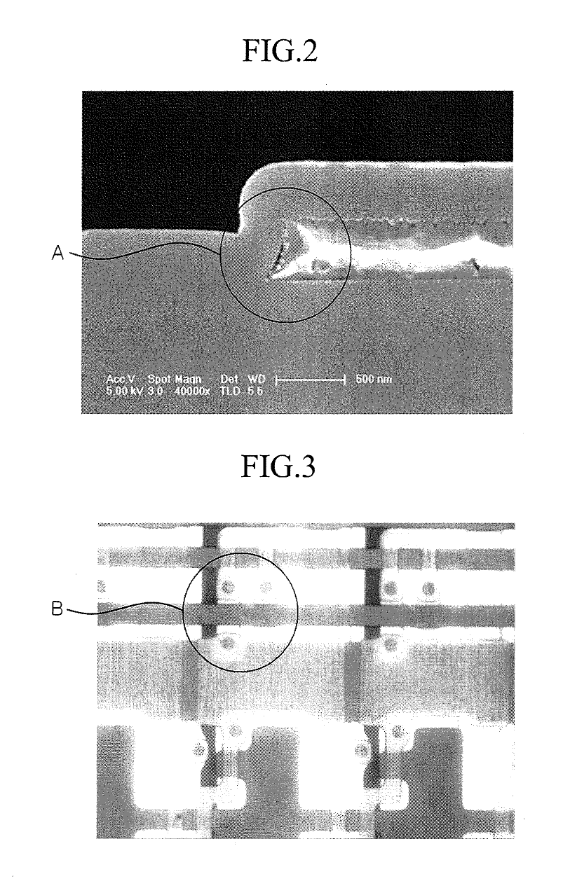

FIG. 2 is a picture of a cross section after forming a source/drain electrode and a pixel defined layer photographed by using a scanning electron microscope (SEM). At this time, even though the source and drain electrodes 101 and 103 are etched by an etching solution used in a known structure of TIO/AG/ITO, etching is normally performed as shown in an area A of FIG. 2. As such, since the etching solution used in the known structure can be used, it is advantageous in that the known etching solution can also be used.

Meanwhile, since the single aluminum alloy layer contains cobalt (Co), the contact resistance between the first conductive layer 50 and the second conductive layer 60 may be low in the TFT region, thereby decreasing the contact resistance between the first conductive layer 50 and the second conductive layer 60.

At this time, only when a sufficient amount of Al₆Co is generated by combining Al and Co with each other, sufficiently low contact resistance may be acquired. When an amount of added Co is too large, fabricating cost is increased and the more an amount of the alloy is, the worse resistance characteristics are. One embodiment adds Co of about 0.2 atom % to about 1.0 atom % of the alloy containing Al and Co.

Other materials having low resistance at the contact portion with the first conductive layer 50 may be used instead of Co. In one embodiment, Ni may be used and Ni of about 0.2 atom % to about 1.0 atom % of the alloy containing Al and Ni may be used.

Further, since the single aluminum alloy layer contains germanium (Ge), it is possible to prevent Al from being infiltrated into a silicon at contact portions between the source and drain electrodes 101 and 103 and the source and drain domains 31 and 33 in the TFT region.

At this time, when Al is infiltrated into the silicon while Ge is insufficient, a junction spike phenomenon is generated when too large amount of Ge is added, the fabricating cost is increased and the more the amount of the alloy is, the worse the resistance characteristics are. One embodiment adds Ge of about 0.5 atom % to about 1.0 atom % of the alloy containing Al and Ge.

FIG. 3 is a picture of a plane after performing a source/drain film-forming process and a pixel defined layer forming process photographed by using a microscope. Referring to the figure, the junction spike phenomenon is not generated as shown in an area B of FIG. 3.

Other materials for preventing Al from being infiltrated into the silicon may be used instead of Ge, for example, Si may be used and Si of about 0.3 atom % to about 1.0 atom % of the alloy containing Al and Si.

Further, since the single aluminum alloy layer contains lanthanum (La), it is possible to prevent a hillock phenomenon of Al while a heat treatment process. At this time, when the amount of the contained La is less than about 0.1 atom % of the Al—La alloy, the hillock phenomenon may frequently be generated and when the amount of La is more than or equal to about 0.5 atom % of the Al—La alloy, the more the amount of the alloy is, the worse the resistance characteristics are. One embodiment adds La of about 0.1 atom % to about 0.5 atom % of the alloy containing Al and La.

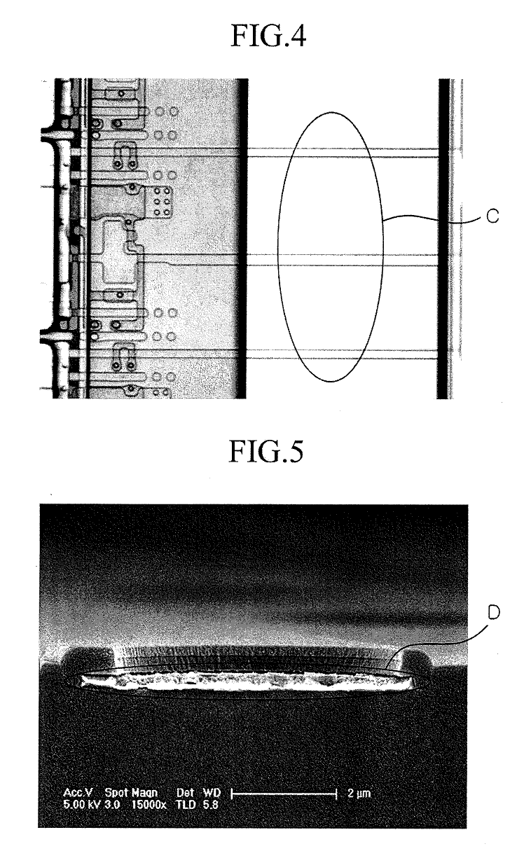

FIG. 4 is a picture of a cathode contact portion photographed by using a microscope in order to verify whether or not hillock is generated. When the hillock is generated, a plurality of spots are formed as shown in an area C of FIG. 4, but in FIG. 4, the spots are not formed, as a result, the hillock is not generated.

FIG. 5 is a picture of a cross section after BOE-washing a contact hole of a pixel area photographed by using an SEM. When the contact hole is influenced by the washing solution, the contact hole is partially melted and removed, but in FIG. 5, the second conductive layer is not influenced by the washing solution as shown in an area D of FIG. 5.

According to at least one of the disclosed embodiments, since both a second conductive layer and a source/drain electrode can be etched by using a single mask, it is possible to decrease the number of lithographic processes.

Further, since a single aluminum alloy layer is used as the second conductive layer and the source/drain electrode, it is easy to develop a common etching solution.

Besides, it is possible to prevent a junction spike phenomenon from being generated at a contact portion between the source/drain electrode and a source/drain region.

Moreover, it is possible to prevent a hillock of aluminum from being generated while performing a heat treatment process. Furthermore, it is possible to prevent degradation or damage to the second conductive layer by a washing solution for a contact hole.

While this disclosure has been described in connection with certain embodiments, it is to be understood to those skilled in the art that the disclosed embodiments are in no way considered limiting. Therefore, the appended claims cover various modifications and equivalent arrangements.

What is claimed is:

1. An organic light emitting diode display, comprising:
a substrate having a thin film transistor region and a pixel region;
a semiconductor layer formed in the thin film transistor region;
a gate insulating layer formed on the substrate and the semiconductor layer;
a lower electrode formed on the gate insulating layer, wherein the lower electrode is formed in the pixel region;
a gate electrode formed on the gate insulating layer, wherein the gate electrode is formed substantially directly above the semiconductor layer;
an interlayer insulating layer formed on the gate insulating layer, the lower electrode and the gate electrode; and
source and drain electrodes formed on the interlayer insulating layer and electrically connected with the semiconductor layer,
wherein each of the lower electrode and the gate electrode is formed of a first conductive layer and a second conductive layer formed on the first conductive layer,
and wherein the second conductive layer and the source/drain electrodes are formed of the same material.

2. The organic light emitting diode display of claim 1, wherein:
the first conductive layer is formed of at least one of the following: ITO, IZO, In203, and Sn203.

3. The organic light emitting diode display of claim 1, wherein:
the second conductive layer and the source and drain electrodes is formed of an Al alloy containing i) one of Co and Ni, ii) one of Ge and Si, and iii) La.

4. The organic light emitting diode display of claim 3, wherein:
the Al alloy contains Co or Ni of about 0.2 atom % to about 1.0 atom % of the Al alloy.

5. The organic light emitting diode display of claim 3, wherein:
the Al alloy contains Ge of about 0.5 atom % to about 1.0 atom % of the Al alloy.

6. The organic light emitting diode display of claim 3, wherein:
the Al alloy contains Si of about 0.3 atom % to about 1.0 atom % of the Al alloy.

7. The organic light emitting diode display of claim 3, wherein:
the Al alloy contains La of about 0.1 atom % to about 0.5 atom % of the Al alloy.

8. The organic light emitting diode display of claim 1, wherein:
an opening is defined in the second conductive layer of the lower electrode.

9. The organic light emitting diode display of claim 8, further comprising:
a pixel defining layer is formed on the entire surface of the interlayer insulating layer and the source and drain electrodes, the pixel defining layer has an opining exposing a part of the first conductive layer;
an organic layer formed on the opening of the pixel defining layer; and
an upper electrode formed on the interlayer insulating layer and the organic layer.

10. The organic light emitting diode display of claim 1, wherein the gate electrode has a thickness of about 2000 Å to about 5000 Å.

11. A method of manufacturing an organic light emitting diode display, comprising:
providing a substrate having a thin film transistor region and a pixel region;
forming a semiconductor layer in the thin film transistor region, wherein the semiconductor layer has a source domain, a drain domain and a channel domain interposed between the source and drain domains;
forming a gate insulating layer on the substrate and the semiconductor layer;
forming a lower electrode on the gate insulating layer, wherein the lower electrode is formed in the pixel region;
forming a gate electrode on the gate insulating layer, wherein the gate electrode is formed substantially directly above the channel domain of the semiconductor layer;
forming an interlayer insulating layer on i) the gate insulating layer, ii) the lower electrode and iii) the gate electrode;
forming first and second contact holes so as to expose part of the lower electrode;
forming third and fourth contact holes so as to expose the source and drain domains of the semiconductor layer; and
forming a source/drain electrode layer on the interlayer insulating layer; and
performing a mask process on the source/drain electrode layer so as to form source and drain electrodes,
wherein each of the lower electrode and the gate electrode is formed of a first conductive layer and a second conductive layer formed on the first conductive layer, and
wherein the second conductive layer and the source and drain electrodes are formed of the same material.

12. The method of claim 11, further comprising:
etching the second conductive layer of the lower electrode so as to expose part of the first conductive layer of the lower electrode, wherein the etching is performed via the same mask process used to form the source and drain electrodes.

13. The method of claim 11, wherein:
the first conductive layer is formed from one of: ITO, IZO, In203, and Sn203.

14. The method of claim 11, wherein:
each of the second conductive layer and the source and drain electrodes is formed of an Al alloy containing i) one of Co and Ni, ii) one of Ge and Si, and iii) La.

15. The method of claim 11, further comprising:
electrically connecting a portion of the lower electrode exposed through the second contact hole and portions of the source and drain domains exposed through the third contact hole by one of the source and drain electrodes.

16. The method of claim 11, wherein:
the lower electrode and the gate electrode are formed through the same mask process.

17. A method of manufacturing an organic light emitting diode display, comprising:
providing a substrate having a thin film transistor region and a pixel region;
forming a semiconductor layer in the thin film transistor region, wherein the semiconductor layer has a source domain, a drain domain and a channel domain interposed between the source and drain domains;
forming a gate insulating layer on the substrate and the semiconductor layer;
forming a lower electrode on the gate insulating layer, wherein the lower electrode is formed in the pixel region;
forming a gate electrode on the gate insulating layer, wherein the gate electrode is formed substantially directly above the channel domain of the semiconductor layer, and wherein each of the lower electrode and the gate electrode is formed of a first conductive layer and a second conductive layer formed on the first conductive layer;
forming an interlayer insulating layer on i) the gate insulating layer, ii) the lower electrode and iii) the gate electrode;
performing a mask process on i) the source/drain electrode layer so as to form source and drain electrodes; and
etching the second conductive layer of the lower electrode so as to expose part of the first conductive layer of the lower electrode, wherein the etching is performed via the same mask process used to form the source and drain electrodes.

18. The method of claim 17, wherein each of the second conductive layer and the source and drain electrodes is formed of an Al alloy containing i) one of Co and Ni, ii) one of Ge and Si, and iii) La.

19. The method of claim 17, wherein the second conductive layer and the source and drain electrodes are formed of the same material.
